(19) United States
(12) Patent Application Publication
(10) Pub. No.: US 2025/0210300 A1
(43) Pub. Date: Jun. 26, 2025

(54) PARTICLE-OPTICAL ARRANGEMENT, IN PARTICULAR MULTI-BEAM PARTICLE MICROSCOPE, WITH A MAGNET ARRANGEMENT FOR SEPARATING A PRIMARY AND A SECONDARY PARTICLE-OPTICAL BEAM PATH

(71) Applicant: Carl Zeiss MultiSEM GmbH, Oberkochen (DE)

(72) Inventors: Dirk ZEIDLER, Oberkochen (DE); Thomas SCHMID, Aalen (DE); Markus KOCH, Neu-Ulm (DE); Felix MENKE, Oberkochen (DE); Thomas DIETERLE, Murrhardt (DE)

(21) Appl. No.: 19/049,631

(22) Filed: Feb. 10, 2025

Related U.S. Application Data
(63) Continuation of application No. PCT/EP2023/025353, filed on Jul. 28, 2023.

(30) Foreign Application Priority Data
Aug. 12, 2022 (DE) 10 2022 120 496.0

(51) Int. Cl. H01J 37/147; H01J 37/26

(52) U.S. Cl. CPC H01J 37/1475; H01J 37/261

(57) ABSTRACT

A particle-optical arrangement includes a magnet arrangement for separating a primary and a secondary particle-optical beam path. The magnet arrangement includes: a first magnetic field region through which the primary particle-optical beam path and the second particle-optical beam path pass, for the separation of the primary particle-optical beam path and the secondary particle-optical beam path from one another; a second magnetic field region arranged in the primary particle-optical beam path and not arranged in the secondary particle-optical beam path; and a third magnetic field region arranged in the primary particle-optical beam path and not arranged in the secondary particle-optical beam path.

### CROSS-REFERENCE TO RELATED APPLICATIONS

The present application is a continuation of, and claims benefit under 35 USC 120 to, international application No. PCT/EP2023/025353, filed Jul. 28, 2023, which claims benefit under 35 USC 119 of German Application No. 10 2022 120 496.0, filed Aug. 12, 2022. The entire disclosure of each of these applications is incorporated by reference herein.

### FIELD

The disclosure relates to a particle-optical arrangement having a beam splitter. The disclosure relates to a particle-optical arrangement, such as a multi-beam particle microscope, with a magnet arrangement for separating a primary particle-optical beam path and a secondary particle-optical beam path.

### BACKGROUND

With the continuous development of ever smaller and ever more complex microstructures such as semiconductor components, there is a desire to further develop and optimize planar production techniques and inspection systems for producing and inspecting small dimensions of the microstructures. By way of example, the development and production of the semiconductor components typically involves monitoring of the design of test wafers, and the planar production techniques often involve process optimization for a reliable production with a high throughput. Moreover, there have been recent demands for an analysis of semiconductor wafers for reverse engineering and for a customer-specific, individual configuration of semiconductor components. Therefore, there is a desire for an inspection mechanism which can be used with a high throughput for examining the microstructures on wafers with a high accuracy.

Typical silicon wafers used in the production of semiconductor components have often diameters of up to 300 mm. Each wafer is typically divided into 30 to 60 repeating regions (“dies”) with a size of up to 800 mm². A semiconductor apparatus can comprise a plurality of semiconductor structures, which are produced in layers on a surface of the wafer by planar integration techniques. Semiconductor wafers typically have a plane surface on account of the production processes. The structure size of the integrated semiconductor structures in this case can extend from a few um to the critical dimensions (CD) of 5 nm, with the structure sizes becoming even smaller in the near future; in future, structure sizes or critical dimensions (CD) are expected to be less than 3 nm, for example 2 nm, or even under 1 nm. In the case of the aforementioned small structure sizes, defects in the size of the critical dimensions is to be identified quickly in a very large area. For several applications, the desired accuracy of a measurement provided by inspection equipment is even higher, for example by a factor of two or one order of magnitude. By way of example, a width of a semiconductor feature is to be measured with an accuracy of below 1 nm, for example 0.3 nm or even less, and a relative position of semiconductor structures is to be determined with an overlay accuracy of below 1 nm, for example 0.3 nm or even less.

The MSEM, a multi-beam scanning electron microscope, is a relatively new development in the field of charged particle systems (charged particle microscopes, CPMs). By way of example, a multi-beam scanning electron microscope is disclosed in U.S. Pat. No. 7,244,949 B2 and in US 2019/0355544 A1. In the case of a multi-beam electron microscope or MSEM, a sample is irradiated simultaneously with a plurality of individual electron beams, which are arranged in a field or raster. By way of example, 4 to 10,000 individual electron beams can be provided as primary radiation, with each individual electron beam being separated from an adjacent individual electron beam by a pitch of 1 to 200 micrometres. By way of example, an MSEM has approximately 100 separate individual electron beams (“beamlets”), which are arranged for example in a hexagonal raster, with the individual electron beams being separated by a pitch of approximately 10 μm. The plurality of charged individual particle beams (primary beams) can be focused on a surface of a sample to be examined by way of a common objective lens. By way of example, the sample can be a semiconductor wafer which is secured to a wafer holder mounted on a movable stage. During the illumination of the wafer surface with the charged primary individual particle beams, interaction products, for example secondary electrons or backscattered electrons, emanate from the surface of the wafer. Their start points generally correspond to those locations on the sample on which the plurality of primary individual particle beams are focused in each case. The amount and the energy of the interaction products generally depend on the material composition and the topography of the wafer surface. The interaction products can form a plurality of secondary individual particle beams (secondary beams), which can be collected by the common objective lens and which are incident on a detector arranged in a detection plane as a result of a projection imaging system of the multi-beam inspection system. The detector can comprise a plurality of detection regions, each of which comprises a plurality of detection pixels, and the detector can capture an intensity distribution for each of the secondary individual particle beams. An image field of, for example, 100 μm×100 μm can be obtained in the process.

A known multi-beam electron microscope comprises a sequence of electrostatic and magnetic elements. At least some of the electrostatic and magnetic elements are adjustable in order to adapt the focus position and the stigmation of the plurality of charged individual particle beams. The multi-beam system with charged particles of the known microscope moreover comprises at least one cross-over plane of the primary or the secondary charged individual particle beams. Moreover, the known system comprises detection systems to make the adjustment easier. The known multi-beam particle microscope comprises at least one beam deflector (“deflection scanner”) for collective scanning of a region of the sample surface via the plurality of primary individual particle beams in order to obtain an image field of the sample surface.

What is known as a beam splitter (or alternatively as a beam separator or beam divider) is used to separate the particle-optical beam path of the primary beams from the particle-optical beam path of the secondary beams. In this case, separation is implemented via special arrangements of magnetic fields and/or electrostatic fields, for example via a Wien filter.

Imaging aberrations arise quite generally as a result of using particle-optical components.

Aberrations within the scope of particle-optical imaging, which are to be corrected where possible, also arise when a beam splitter is used. Ideally, imaging aberrations should be avoided or corrected for all individual particle beams. The corrections normally become ever more important as image fields become ever more extensive within the scope of the particle-optical imaging. An image field can be particularly extensive in the case of multi-beam particle microscopes which operate with a plurality of individual particle beams (multi-image field, so-called mFOV).

To correct aberrations due to beam splitters of multi-beam particle microscopes, EP 1 668 662 B1 discloses the provision of a further magnetic sector field in the primary path upstream of the actual separating magnetic sector field. Aberrations in the secondary path are corrected by up to three further magnetic sector fields in the secondary path.

U.S. Pat. No. 9,153,413 B2 discloses a further beam splitter for multi-beam particle microscopes, in the case of which there is a correction of beam splitter-induced aberrations. The beam splitter operates according to the Wien filter principle. To correct aberrations, alignments or skews of individual particle beams are respectively corrected singly or individually via multi-deflector arrays following the passage through the beam splitter.

### SUMMARY

With increasing demands on the resolution of multi-beam particle microscopes, there are also increasing demands on corrections of aberrations. Thus, there is a desire for improvement overall in the context of the correction of beam splitter-induced imaging aberrations.

The disclosure seeks to provide a particle-optical arrangement, such as a multi-beam particle microscope, by which beam splitter-induced aberrations, which occur in the primary path in particular, can be better corrected.

The aberrations which typically may occur in the case of multi-beam particle microscopes include, for example, spherical aberrations, astigmatism, coma, field curvature, distortion, chromatic aberrations or dispersion, etc. In the case of the multi-beam particle microscope, described in EP 1 668 662 B1, with the beam splitter already briefly described in the Background section above or the above-described arrangement of magnetic sector fields or magnetic field regions, imaging the plurality of first individual particle beams into the object plane can substantially already be, overall, substantially stigmatic in the first order and substantially distortion-free in the first order, and moreover dispersion-free. This should still be possible. The full disclosure of EP 1 668 662 B1 is incorporated in the present patent application by reference.

Following a first approach, attempts were therefore made to provide additional correction elements for the existing beam splitter while leaving the beam splitter itself substantially unchanged. By way of example, this approach was followed for a field curvature correction.

However, more recent, more precise examinations (highly precise measurements of what is known as a focus map) have surprisingly shown that the remaining leading residual error during the particle optical imaging often is not the field curvature but the field inclination. In the case of field inclination, the focal position of first individual particle beams in relation to the (ideal) object plane changes linearly with the distance from the optical axis; by contrast, the focal position changes quadratically with the distance from the optical axis in the case of field curvature. Several compensators for correcting a field inclination have already been proposed in DE 2021 200 799 B3.

Unlike field curvature, for example, the field inclination is a non-rotationally symmetric aberration. A possible cause for non-rotationally symmetric aberrations in the case of existing beam splitters can be found in a break of symmetry in the case of the beam splitters. An angle (“skew angle”) between the optical axis upon entrance of the primary beams into the beam splitter and the optical axis upon emergence of the primary beams from the beam splitter may contribute to this break of symmetry. The present disclosure proposes a modified design for the beam splitter itself, or for the associated magnet arrangement. For example, field inclination can be corrected at the same time, or the latter does not even arise in the case of an appropriately chosen design of the beam splitter: This is because the field inclination is substantially the result of slight path differences between various individual particle beams when passing through the beam splitter. According to examinations by the inventors, these path differences decisively arise as a result of an angle (a so-called “skew angle”) existing between the optical axis upon entrance of the primary beams into the beam splitter and the optical axis upon emergence of the primary beams from the beam splitter in the case of the design according to EP 1 668 662 B1. Thus, the primary beam column is slightly tilted vis-à-vis the remaining structure or vis-à-vis the lower region of the column in the region of the objective lens and a sample. Likewise, a non-exactly collimated entrance of the individual particle beams into the beam splitter may contribute to path length differences, just like inclinations of depressions of the magnetic field regions or sectors with respect to the optical axis.

Thus, an aligned optical axes design is proposed according to the disclosure for the beam splitter, the design moreover offering at least as many or even more manipulation parameters for correcting aberrations in comparison with the design already known from the prior art. The skew angle can be dispensed with in the case of the aligned optical axes design, potentially offering huge benefits during the manufacture and adjustment of multi-beam particle microscopes, in addition to the improved imaging properties of the beam splitter.

According to a first aspect, the disclosure relates to a particle-optical arrangement for providing a primary particle-optical beam path for a plurality of first individual charged particle beams which, emanating from a multi-beam particle generator, are directed at an object positionable in an object plane of the arrangement, and a secondary particle-optical beam path for a plurality of second individual charged particle beams which emanate from the object, wherein the particle-optical arrangement has a magnet arrangement comprising:
a first magnetic field region through which the primary particle-optical beam path and the second particle-optical beam path pass, for the separation of the primary particle-optical beam path and the secondary particle-optical beam path from one another;
a second magnetic field region arranged in the primary particle-optical beam path and not arranged in the secondary particle-optical beam path, the second magnetic field region being arranged upstream of the first magnetic field region in relation to the primary particle-optical beam path and the first magnetic field region and the second magnetic field region substantially deflecting the primary particle-optical beam path in different directions;
a third magnetic field region arranged in the primary particle-optical beam path and not arranged in the secondary particle-optical beam path, the third magnetic field region being arranged upstream of the second magnetic field region in relation to the primary particle-optical beam path and the first and the third magnetic field region substantially deflecting the primary particle-optical beam path in the same direction,
   an entrance direction of the primary particle-optical beam path into the third magnetic field region and an exit direction of the primary particle-optical beam path from the first magnetic field region being substantially parallel to one another and substantially without an offset. As a result of this condition, the magnet arrangement thus has “aligned optical axes” for the primary particle-optical beam path. This aligned optical axes property can be obtained with great accuracy; an error or an angle between the entrance direction of the primary particle-optical beam path into the third magnetic field region and the exit direction of the primary particle-optical beam path from the first magnetic field region in the case of an aligned optical axes property is less than or equal to 4 mrad, such as less than or equal to 1 mrad, for example less than or equal to 0.1 mrad. An error in the offset-free property is likewise very small, for example no more than +/−0.6 mm, such as +/−0.3 mm, +/−0.1 mm or even +/−0.05 mm.

By way of example, if the particle-optical arrangement is a multi-beam particle microscope, then—unlike in certain prior art-the plurality of first individual particle beams can reach a sample even if the beam splitter or the magnet arrangement is switched off. In this way, the intended operation of the magnet arrangement and other particle-optical imaging elements can be checked substantially more easily. The manufacture of the multi-beam particle microscope overall is also substantially simplified in this way.

A deflection of particle beams substantially in the same direction can be realized using magnetic fields pointing substantially in the same direction; in this case, the magnetic field strengths in the two magnetic field regions may be identical or may differ.

A deflection of particle beams substantially in different direction can be realized using magnetic fields pointing substantially in opposite directions; in this case, the magnetic field strengths in the two magnetic field regions may be substantially identical or may differ.

As a result of the primary path of the particle-optical arrangement providing one more magnetic field region than in the prior art, the magnet arrangement also can offer sufficient options for optimization approaches for the purpose of correcting aberrations. This is because there are at least as many independent manipulation parameters present as in the previous system. Manipulation parameters for the magnet arrangement are, for example, the positions (height or z-positions) of the entrance points and exit points into/from the various magnetic field regions and the associated entrance or exit angles. By defining these manipulation parameters, it is possible (for a given magnetic field and a given kinetic energy of the charged particles) to set the respective arc length in a magnetic field region, along which the first individual charged particle beams move through the magnetic field regions.

The magnetic field regions themselves can be formed in a manner that is known per se. They can be designed for example to form homogeneous magnetic fields, with the direction of the magnetic field being oriented orthogonal to the movement direction of the first individual particle beams. By way of example, the magnetic field regions can each be formed by two spaced apart slabs of magnetizable material, each with milled depressions into which current conductors or coils have been inserted. However, other embodiments are also possible.

The first individual charged particle beams can be, for example, electrons, positrons, muons or ions or other charged particles. The second individual charged particle beams can be mirror particles of the first individual charged particle beams; they can be secondary electrons or backscattered electrons. In general, the particle-optical arrangement is therefore flexibly usable.

The terms primary particle-optical beam path and secondary particle-optical beam path are conventional in the art. However, attention is drawn here to the fact that the primary particle-optical beam path, just like the secondary particle-optical beam path, describes the paths of the plurality of first or second individual particle beams. For simplification, it may however naturally be—depending on context—that the terms primary particle-optical beam path and secondary particle-optical beam path only reference an individual particle beam, moving along the optical axis of the system, or the central beam.

According to an embodiment of the disclosure, a first drift region, which is substantially free from magnetic fields, is arranged in the primary particle-optical beam path between the first magnetic field region and the second magnetic field region; and/or a second drift region, which is substantially free from magnetic fields, is arranged in the primary particle-optical beam path between the second magnetic field region and the third magnetic field region. In this case, the first and the second drift region may have different lengths and different orientations. The provision of drift regions between the magnetic field regions can be desirable in terms of the design of the particle-optical arrangement, especially in the case of a given entrance point into and given exit point from the particle-optical arrangement: This is because this case leads to more mutually independent manipulation parameters for the magnet arrangement, offering more options for the correction of imaging aberrations. Moreover, a greater distance between the magnetic field regions can contribute to the reduction or avoidance of interaction effects between the magnetic field regions. Moreover, a spatial separation between the primary particle beams and the secondary particle beams can also be facilitated.

According to an embodiment of the disclosure, the magnet arrangement has a fourth magnetic field region which is arranged in the primary particle-optical beam path and not arranged in the secondary particle-optical beam path, wherein the fourth magnetic field region is arranged upstream of the second magnetic field region and downstream of the third magnetic field region in relation to the primary particle-optical beam path, and wherein the fourth magnetic field region and the second magnetic field region substantially deflect the primary particle-optical beam path in the same direction. The provision of a fourth magnetic field region can allow for further manipulation parameters being available for the correction of aberrations. These may be up to four further manipulation parameters (for example, entrance height into and exit height from the magnetic field region and the inclination of the magnetic field regions or trenches in relation to the optical axis of the primary particle-optical beam path upon entrance or exit).

According to an embodiment of the disclosure, the particle-optical arrangement has a first drift region, which is substantially free from magnetic fields and which is arranged in the primary particle-optical beam path between the first magnetic field region and the second magnetic field region. In addition, or as an alternative, the particle-optical arrangement has a second drift region, which is substantially free from magnetic fields and which is arranged in the primary particle-optical beam path between the second magnetic field region and the fourth magnetic field region. In addition, or as an alternative, the particle-optical arrangement has a third drift region, which is substantially free from magnetic fields and which is arranged in the primary particle-optical beam path between the fourth magnetic field region and the third magnetic field region. In this embodiment variant of the disclosure provision of drift regions contributes to increasing the number of parameters of the magnet arrangement that are adjustable independently of one another.

According to an embodiment of the disclosure, the magnet arrangement has no further magnetic field regions in the primary particle-optical beam path which are designed to deflect the primary particle-optical beam path by more than 2°, such as by more than 1°, for example by more than 0.5°. In other words, either exactly three magnetic field regions or exactly four magnetic field regions should be provided in the primary particle-optical beam path according to this embodiment. Restricting the number of magnetic field regions in the primary particle-optical beam path can mean that the plurality of the first individual particle beams are not focused too strongly overall during the movement through the magnet arrangement. This is because, on account of arising quadrupole fields, the first individual charged particle beams each experience focusing, albeit weak focusing, upon entrance into or exit from each magnetic field region. Limiting the magnetic field regions to a comparatively small number simultaneously also limits this focusing, which is, in general, unwanted.

According to an embodiment of the disclosure, the magnet arrangement of the particle-optical arrangement is configured so that substantially no path differences arise for the plurality of the first individual particle beams as these pass through the magnet arrangement. By way of example, this can eliminate or reduce field inclination.

According to an embodiment of the disclosure, the magnet arrangement of the particle-optical arrangement has a plane of symmetry, in relation to which the primary particle-optical beam path is mirror symmetric when passing through the magnet arrangement. Thus, this plane of symmetry can then be located halfway up between the entrance point of the primary particle-optical beam path into the magnet arrangement overall and the exit point of the primary particle-optical beam path from the magnet arrangement overall.

Should the magnet arrangement have exactly three magnetic field regions overall, the plane of symmetry can intersect the second magnetic field region. Should the magnet arrangement have four magnetic field regions overall, the plane of symmetry can be arranged between the second magnetic field region and the fourth magnetic field region. The symmetry condition in respect of the plane of symmetry relates to the particle-optical beam path and, for example, to the chief ray; it does not automatically also relate to the design of the magnetic field regions themselves. Nevertheless, some magnetic field regions may have identical or mirror-identical dimensions, which may be desirable from a manufacturing point of view. Moreover, five second-order aberration terms (of a total of 18 linearly independent second-order aberration terms) can be eliminated as a result of the symmetric design of the magnet arrangement. In general, each symmetry property reduces the number of manipulation parameters that are adjustable independently of one another. Nevertheless, a sufficient number of manipulation parameters that are adjustable independently of one another can remain as a matter of principle if corresponding drift paths are provided in the magnet arrangement, as already described in detail hereinabove.

According to an embodiment of the disclosure, the direction of the magnetic fields in all of the magnetic field regions of the magnet arrangement is substantially orthogonal to the optical axis of the primary particle-optical beam path during the operation of the particle-optical arrangement and the magnetic fields are substantially homogeneous. The trajectories in the magnet arrangement (circular trajectories or helical trajectories with a trajectory radius r_{B}) described by the first individual particle beams thus can be adjustable in a better and more precise manner. For example, the following may apply to a trajectory radius r_{B}: 0.1 m≤r_{B}≤10.0 m.

According to an embodiment of the disclosure, the homogeneous magnetic fields in the magnetic field regions in the primary particle-optical beam path each have an absolute value of the magnetic field strength during the operation of the particle-optical arrangement and the magnetic fields are each assigned a sign, the sign characterizing the direction of the magnetic field, and wherein the sum of the products of the signed absolute value of the magnetic field strength and an associated circular arc length in a magnetic field region, along which the primary particle-optical beam path travels in the magnetic field region, summed over all magnetic field regions in the primary particle-optical beam path yields zero to a first approximation. This condition applies to a first approximation for the central beam. This is a desireable, but not yet sufficient condition for the aligned optical axes property of the magnet arrangement. The entrance direction of the primary particle-optical beam path into the third magnetic field region and the exit direction of the primary particle-optical beam path from the first magnetic field region then can be substantially parallel to one another. However, an offset may still occur in principle. The latter can be eliminated by an appropriate choice of drift paths or their lengths. By way of example, if a total of three magnetic field regions are present and if a first and second drift region are respectively arranged between two magnetic field regions, then the lengths of the two drift regions have to be identical in order to not have an offset. By way of example, if a total of four magnetic field regions are provided for the magnet arrangement and if a respective drift region is provided between two magnetic field regions, then the length of the first and the last drift region can for example be chosen to be identical and the central drift region extends parallel to the (already exhibiting vector identity) entrance direction or exit direction of the primary particle-optical beam path into/from the magnet arrangement. Quite generally, it holds true for a magnet arrangement with aligned optical axes in relation to the primary particle-optical beam path that a vector summation of drift paths overall yields a vector which is a multiple of the entrance direction of the primary particle-optical beam path into the magnet arrangement overall. In any case, this can apply if the magnetic field strength is identical in all magnetic field regions. In addition to the above condition for the particle-optical beam path of the central beam, the magnet arrangement can be designed so that there are substantially no path length differences between various first individual particle beams when travelling through the magnet arrangement, even for off-axis beams in the case of a divergent or convergent entrance of the first individual particle beams into the magnet arrangement and/or in the case of a divergent or convergent emergence of the first individual particle beams from the magnet arrangement.

According to an embodiment of the disclosure, the following relation applies to a splitting angle y through which the primary particle-optical beam path is deflected overall in the first magnetic field region during the operation of the particle-optical arrangement: γ≥2°, such as γ≤5°, for example γ≥10°. The splitting angle in this case is a measure for the maximum possible separation of the primary particle-optical beam path from the secondary particle-optical beam path. The splitting angle γ is not be chosen to be too small, otherwise further magnetic field regions for the secondary particle-optical beam path cannot be integrated in the magnet arrangement of the particle-optical arrangement without problems. By way of example, further magnetic field regions which should be assigned exclusively to the secondary particle-optical beam path might collide with the magnetic field regions of the primary particle-optical beam path. By way of example, this may lead to crosstalk between various magnetic field regions.

According to an embodiment of the disclosure, an overall length of the magnet arrangement, as defined by a distance between the entrance point of the primary particle-optical beam path into the third magnetic field region and the exit point of the primary particle-optical beam path from the first magnetic field region, is less than or equal to 1.0 m, such as less than or equal to 0.5 m, for example less than or equal to 0.3 m.

According to an embodiment of the disclosure, each magnetic field region has an entrance region for the primary particle-optical beam path with an entrance inclination and an exit region for the primary particle-optical beam path with an exit inclination, wherein the exit inclination of the first magnetic field region is substantially 0°. Here, the entrance inclination is defined as the angle by which the alignment of the entrance region deviates from the normal to the optical axis of the primary particle-optical beam path, and the exit inclination is defined as the angle by which the alignment of the exit region deviates from the normal to the optical axis of the primary particle-optical beam path. Stipulating that the exit inclination of the first magnetic field region is substantially 0° ensures that the optical axis of an objective lens further down in the primary particle-optical beam path may correspond or coincide with the exit direction of the primary particle-optical beam path. This can facilitate the further configuration of the particle-optical arrangement overall.

According to an embodiment of the disclosure, the entrance inclination of the third magnetic field region is substantially 0°. This can likewise further facilitate the further configuration of the particle-optical arrangement in the primary particle-optical beam path and, at the same time, the 0° inclination may represent a condition for establishing the symmetry in the aligned optical axes magnet arrangement.

According to an embodiment of the disclosure, the particle-optical arrangement further has a deflector arrangement arranged upstream of the third magnetic field region in the direction of the primary particle-optical beam path and configured to set the entrance direction of the primary particle-optical beam path into the third magnetic field region, and hence set the used entrance inclination of 0° for example, with an accuracy of +/−0.1° or better, such as +/−0.05° or better, for example +/−0.025° or better, and configured to set the entrance location of the primary particle-optical beam path into the third magnetic field region with an accuracy of +/−0.3 mm or better, such as +/−0.1 mm, for example +/−0.05 mm or better. The deflector arrangement can comprise two adjustment deflectors which can be adjusted precisely and independently of one another such that it is possible to set, precisely and independently of one another, both the offset and the skew of the first individual particle beams upon entrance into the magnet arrangement. This can help prevent a possible recurrence of beam splitter aberrations, actually already corrected by the design of the magnet arrangement, such as field inclination, field astigmatism, global astigmatism or other second- or third-order aberrations in the case of a skewed or offset beam input coupling.

According to an embodiment of the disclosure, the entrance inclination of the first magnetic field region is chosen so that an exit angle σ of the secondary particle-optical beam path from this first magnetic field region is restricted to σ≤35°, such as σ≤25°,for example σ≤15°. This can help avoid the collection of large aberrations when emerging from the first magnetic field region and creates additional installation space for possible additional secondary path magnetic field regions in the gap between the first magnetic field region and the second magnetic field region. More details in this respect will be given hereinbelow.

According to an embodiment of the disclosure, the magnet arrangement has a beam tube arrangement, within which the primary particle-optical beam path extends within the magnet arrangement, wherein the beam tube arrangement has the topological form of a torus. As a result, the aligned optical axes property of the magnet arrangement can be used for adjustment purposes when the primary path beam splitter is switched off or when magnetic field regions in the primary particle-optical beam path are switched off. The torus topology describes very generally two branches of the beam tube arrangement, wherein, when the magnetic field regions are switched off, the primary particle-optical beam path can branch off at the first branching and can be coupled back in at the second branching.

According to an embodiment of the disclosure, the following relation applies to a fill factor F of the beam tube arrangement during the operation of the particle-optical arrangement: F≤50%, such as F≤30%, for example F≤10%. In this case, the fill factor is given as the ratio of the maximum diameter S of a beam (the totality of the primary individual particle beams) to the internal diameter R of the beam tube or the beam tube arrangement. In this case, the beam tube is made of a non-magnetic material. For a given maximum diameter S of the beam, the internal diameter R of the beam tube can be dimensioned accordingly. This can help minimize the contamination of the beam tube as a result of the interaction with the charged particle beams during operation, in order to help avoid unwanted beam deflections on account of charged contamination spots on the inner side of the beam tube.

According to an embodiment of the disclosure, the magnet arrangement comprises no beam tube arrangement in which the primary particle-optical beam path extends within the magnet arrangement. A known beam tube arrangement can limit the room for the individual particle beams to manoeuvre when passing through the magnet arrangement. However, if it should be possible to check the primary particle-optical beam path in a switched-off state of the magnet arrangement in the aligned optical axes design of the magnet arrangement according to the disclosure, then the limitation of the room for the particle beams to maneuver given by the beam tube arrangement may be a hindrance. More details can be gathered for example from GB000002519511A, the full disclosure of which is incorporated in the present patent application by reference. According to an embodiment of the disclosure, the magnet arrangement therefore has a vacuum chamber in which the primary particle-optical beam path and/or the secondary particle-optical beam path extends/extend within the magnet arrangement. The desired free mobility of the individual particle beams can be provided within this vacuum chamber. In principle, arranging or fastening the individual magnetic field regions in the vacuum chamber can be implemented in a manner already known per se.

According to an embodiment of the disclosure, the magnet arrangement has at least two further magnetic field regions in the secondary particle-optical beam path following the passage of the first magnetic field region, the at least two further magnetic field regions being configured, in the case of a varying energy of secondary particles whose path forms the second particle-optical beam path, to precisely input couple, in terms of offset and angle, the particle-optical axis in the secondary beam path into a downstream projection optical unit. By way of example, the varying energy of the secondary particles may be the result of a modified setting of a landing energy.

According to an embodiment of the disclosure, the magnet arrangement has at least six further magnetic field regions and/or quadrupole fields in the secondary particle-optical beam path following the passage of the first magnetic field region, the at least six further magnetic field regions and/or quadrupole fields being configured, in the case of a varying energy of secondary particles whose path forms the second particle-optical beam path, to precisely input couple, in terms of offset and angle, the particle-optical axis in the secondary beam path into a downstream projection optical unit and additionally enable paraxial stigmatic, paraxial distortion-free and paraxial dispersion-free imaging.

According to an embodiment of the disclosure, at least one of the further magnetic field regions of the secondary particle-optical beam path is arranged in a gap between the first magnetic field region and the second magnetic field region of the primary particle-optical beam path.

According to an embodiment of the disclosure, the magnet arrangement further has a magnetic shielding wall arranged between at least one of the magnetic field regions of the primary particle-optical beam path and at least one of the magnetic field regions of the secondary particle-optical beam path. Naturally, it may also be arranged substantially continuously between all magnetic field regions of the primary particle-optical beam path and all magnetic field regions of the secondary particle-optical beam path. By way of example, the magnetic shielding wall comprises a web of soft magnetic material, which minimizes crosstalk between primary path and secondary path magnetic field regions.

According to an embodiment of the disclosure, the magnetic shielding wall has an opening channel, through which the first particle-optical beam path passes in a straight line along the particle-optical axis when the magnet arrangement is switched off. As a result, the aligned optical axes property of the magnet arrangement when the magnetic field regions of the primary path are switched off can be used for adjustment purposes. The opening channel can be characterized by the ratio K of channel length L to channel width B. For example, in the case of K≥3, such as K≥5, for example K≥10, the magnetic shield between the magnetic field regions of the primary path and secondary path can be well ensured despite the opening channel.

According to an embodiment of the disclosure, the particle-optical arrangement is a multi-beam particle microscope and the particle-optical arrangement further has the following:
a multi-beam particle generator, which is configured to generate a first field of a plurality of charged first individual particle beams; a first particle-optical unit with a primary particle-optical beam path, configured to image the generated first individual particle beams onto an object plane such that the first individual particle beams impinge an object at incidence locations, which form a second field; a detection unit with a plurality of detection regions which form a third field; a second particle-optical unit with a secondary particle-optical beam path, configured to image second individual particle beams, which emanate from the incidence locations in the second field, onto the third field of the detection regions of the detection system; a magnetic and/or electrostatic objective lens, through which both the first and the second individual particle beams pass; and a controller, configured to control particle-optical components in the primary and/or in the secondary particle-optical beam path and/or components of the magnet arrangement, wherein the magnet arrangement is arranged in the first particle-optical beam path between the multi-beam particle generator and the objective lens and wherein the magnet arrangement is arranged in the second particle-optical beam path between the objective lens and the detection unit.

The first individual charged particle beams can be, for example, electrons, positrons, muons or ions or other charged particles. It can be beneficial for the number of first individual particle beams to be 3n(n−1)+1, where n is any natural number. The first individual particle beams can then be arranged in a hexagonal field. However, other arrangements of the first individual particle beams are also possible. The second individual particle beams can be backscattered electrons or else secondary electrons. In this case, for analysis purposes, it is desirable for the low-energy secondary electrons to be used for image generation. However, it is also possible for mirror ions/mirror electrons to be used as second individual particle beams, which is to say first individual particle beams undergoing reversal directly upstream of the object or at the object.

Naturally, the magnet arrangement of the multi-beam particle microscope can still be extended or improved for the secondary particle-optical beam path, as has already been described hereinabove. According to an embodiment, the magnet arrangement has at least one further magnetic field region in the secondary particle-optical beam path. By way of example, it is possible to arrange one or two or three further magnetic field regions in the secondary particle-optical beam path, as has already been described in the prior art in EP 1 668 662 B1. As a result, imaging aberrations as a result of the magnet arrangement or the beam splitter can also be corrected in the secondary particle-optical beam path.

According to an embodiment of the disclosure, imaging of the plurality of the first individual particle beams onto the object plane exhibits substantially no field inclination. Naturally, it is also possible to correct other imaging aberrations by way of an appropriate design of the magnet arrangement, as has also already been described in detail hereinabove.

According to an embodiment of the disclosure, the imaging of the plurality of the first individual particle beams into the object plane is substantially distortion-free overall, and/or
the imaging of the first individual particle beams into the object plane is substantially dispersion-free, and/or the incidence locations of the first individual particle beams in the object plane are astigmatic and round. In addition, or as an alternative, it is also possible to correct other aberrations within the scope of the particle-optical imaging. Depending on the design, the magnet arrangement according to the disclosure offers appropriate manipulation parameters for correction purposes. The correction may also comprise a correction of a skew of the sample and/or a correction of a focal tilt as a result of a maladjustment of an illumination system/condenser lens system.

According to an embodiment of the disclosure, the imaging of the first individual particle beams into the object plane is field astigmatism-free.

According to an embodiment of the disclosure, the sum of all other aberrations of second and third order in the object plane is no more than only 1 nm, in particular no more than only 0.5 nm or no more than only 0.25 nm.

The above-described embodiments can be combined with one another in full or in part, provided that no technical contradictions arise as a result.

### BRIEF DESCRIPTION OF THE DRAWINGS

The disclosure will be understood even better with reference to the accompanying figures, in which:

FIG. 1: schematically shows a multi-beam particle microscope;

FIG. 2: schematically shows a multi-beam particle microscope with a beam splitter or magnet arrangement according to the prior art;

FIG. 3: schematically shows a magnet arrangement according to the prior art and the occurrence of a field inclination;

FIG. 4: schematically shows manipulation parameters in the case of a magnet arrangement with two magnetic field regions in the primary path;

FIG. 5: schematically shows manipulation parameters in the case of a magnet arrangement with three magnetic field regions in the primary path; schematically shows manipulation parameters in the case of a symmetrized FIG. 6: magnet arrangement with three magnetic field regions in the primary path; schematically shows manipulation parameters in the case of a symmetrized FIG. 7: magnet arrangement with four magnetic field regions in the primary path; and

FIG. 8: schematically illustrates an arrangement or alignment of the first magnetic field region in the particle-optical beam path.

### DETAILED DESCRIPTION

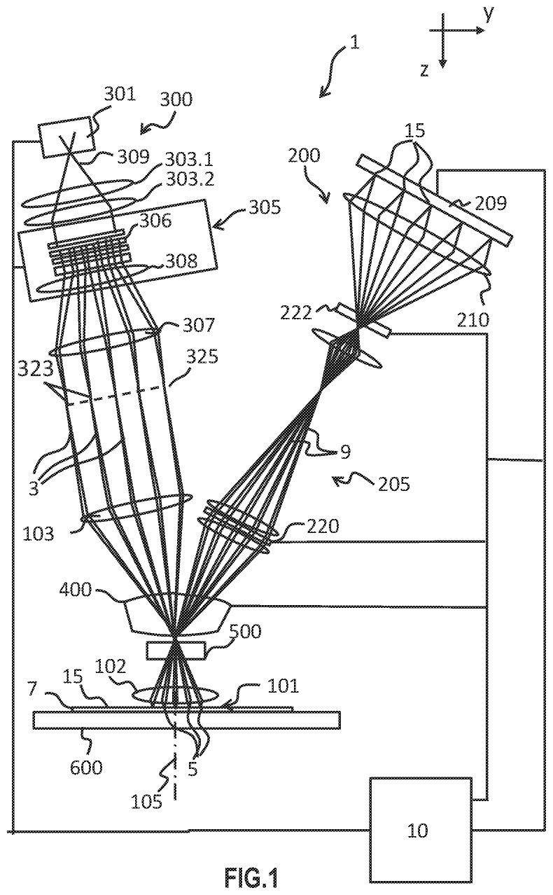

FIG. 1 schematically shows a multi-beam particle microscope 1. The multi-beam particle microscope 1 comprises a beam generating apparatus 300 with a particle source 301, for example an electron source. A divergent particle beam 309 is collimated by a sequence of condenser lenses 303.1 and 303.2, and strikes a multi-aperture arrangement 305. The multi-aperture arrangement 305 comprises a plurality of multi-aperture plates 306 and a field lens 308. A plurality of individual particle beams 3 or individual electron beams 3 is generated by the multi-aperture arrangement. Midpoints of apertures in the multi-aperture plate arrangement are arranged in a field which is imaged onto a further field formed by beam spots 5 in the object plane 101. The pitch between midpoints of apertures of a multi-aperture plate 306 can be 5 μm, 100 μm and 200 μm, for example. The diameters D of the apertures are smaller than the pitch of the midpoints of the apertures, examples of the diameters are 0.2-times, 0.4-times and 0.8-times the pitches between the midpoints of the apertures.

The multi-aperture arrangement 305 and the field lens 307 are configured to generate a multiplicity of focal points 323 of primary beams 3 in a raster arrangement on a surface 325. The surface 325 need not be a plane surface but can be a spherically curved surface in order to account for field curvature of the subsequent particle-optical system.

The multi-beam particle microscope 1 further comprises a system of electromagnetic lenses 103 and an objective lens 102, which image the beam foci 323 with reduced size from the intermediate image surface 325 into the object plane 101. In between, the first individual particle beams 3 pass through the beam splitter 400 and a collective beam deflection system 500, by which the plurality of first individual particle beams 3 are deflected when in operation and the image field is scanned. The first individual particle beams 3 incident in the object plane 101 for example form a substantially regular field, wherein pitches between adjacent incidence locations 5 can be 1 μm, 10 μm or 40 μm, for example. By way of example, the field formed by the incidence locations 5 may have a rectangular or hexagonal symmetry.

The object 7 to be examined can be of any desired type, for example a semiconductor wafer or a biological sample, and can comprise an arrangement of miniaturized elements or the like. The surface 15 of the object 7 is arranged in the object plane 101 of the objective lens 102. The objective lens 102 may comprise one or more electron-optical lenses. By way of example, this may be a magnetic objective lens and/or an electrostatic objective lens.

The primary particles 3 incident on the object 7 generate interaction products, for example secondary electrons, backscattered electrons or primary particles which have experienced a reversal of movement for other reasons, and these interaction products emanate from the surface of the object 7 or from the first plane 101 or object plane 101. The interaction products emanating from the surface 15 of the object 7 are shaped by the objective lens 102 to form secondary particle beams 9. In the process, the secondary beams 9 pass through the beam splitter 400 after the objective lens 102 and are supplied to a projection system 200. The projection system 200 comprises an imaging system 205 with first and second lenses 210 and 220, a contrast stop 222 and a multi-particle detector 209. Incidence locations of the second individual particle beams 9 on detection regions of the multi-particle detector 209 are located in a third field with a regular pitch from one another. Exemplary values are 10 μm, 100 μm and 200 μm.

The multi-beam particle microscope 1 further has a computer system or control unit 10, which in turn may be made of one part or many parts and which is designed both to control the individual particle-optical components of the multi-beam particle microscope 1 and to evaluate and analyse the signals obtained by the multi-detector 209 or detection unit 209.

Further information relating to such multi-beam particle beam systems or multi-beam particle microscopes 1 and components used therein, such as, for instance, particle sources, multi-aperture plates and lenses, can be obtained from the international patent applications WO 2005/024881 A2, WO 2007/028595 A2, WO 2007/028596 A1, WO 2011/124352 A1 and WO 2007/060017 A2 and the German patent applications DE 10 2013 016 113 A1 and DE 10 2013 014 976 A1, the full disclosure of which is incorporated in the present application by reference.

The beam splitter 400 or magnet arrangement 400 is depicted only schematically and without further details in FIG. 1. In principle, it is possible for the magnet arrangement 400 to be the magnet arrangement 400 which is contained in the particle-optical arrangement according to the disclosure. However, the beam splitter 400 known from the prior art or from EP 1 668 662 B1 is also compatible with the multi-beam particle microscope 1 according to FIG. 1.

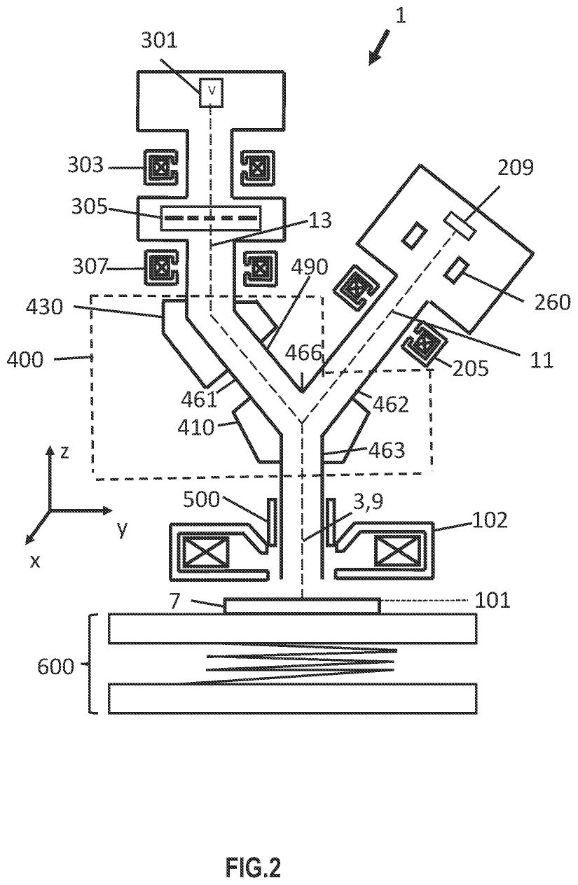

FIG. 2 schematically shows a sectional illustration of a multi-beam particle microscope 1 with a beam splitter 400 or magnet arrangement 400 according to the prior art. Special aspects of the known beam splitter 400 are explained here. In the multi-beam particle microscope 1 depicted in FIG. 2, a particle beam which is emitted by a particle source 301 passes through a magneto-optic condenser lens system 303 and subsequently strikes the multi-aperture arrangement 305. The latter serves as a multi-beam particle generator, and individual particle beams 3 emanating from the multi-aperture arrangement 305 thereupon pass through a magneto-optic field lens system 307 and subsequently enter the magneto-optic beam splitter 400 or magnet arrangement 400. The depicted beam splitter 400 comprises a beam tube arrangement 490, which has a Y-shaped embodiment and comprises three limbs 461, 462 and 463 in the example shown. Here, in addition to two flat, interconnected structures for holding the magnetic sectors or magnetic field regions 410, 430, the beam splitter 400 includes the two magnetic sectors or magnetic field regions 410 and 430 which are contained in, or secured to, the structures. After passing through the beam splitter 400, the first particle beams 3 pass through a scan deflector 500 and, thereupon, the particle-optical objective lens 102, before the primary particle beams 3 are incident on the surface 15 of an object 7, in this case a semiconductor wafer with HV structures. In this case, HV structures denote the predominantly horizontal or vertical profile of semiconductor structures. In this case, the semiconductor wafer 7 is positioned by a displacement stage 600 below the objective lens 102. As a result of the incidence of the first individual particle beams 3, secondary particles or second individual particle beams 9 are released from the object 7. After emerging from the object 7, the second individual particle beams 9 initially pass through the particle-optical objective lens 102 and subsequently pass through the scan deflector 500 and then the beam splitter 400. From the beam splitter 400, the second individual particle beams 9 emerge from the limb 462, pass through a projection lens system 205 (illustrated in much-simplified fashion), pass through an electrostatic element 260, the so-called anti-scan, and then impinge a particle-optical detection unit 209. The computer system 10 or the control unit 10, serving to control particle-optical components and other constituent parts of the multi-beam particle microscope 1 according to FIG. 2, is not depicted in FIG. 2 in order to keep things simple.

From the beam splitter 400 according to the prior art, it is clear that the provision of a beam tube arrangement 490 can offers be beneficial for the shown structure and for the desired evacuation of the surroundings of the first and second particle-optical beam path 13 and 11, respectively, within the beam splitter 400. However, it is also evident that the first particle-optical beam path 13 cannot pass through the beam splitter 400 when the beam splitter 400 is in the switched off state, and instead strikes the walls of the beam tube arrangement 490. This makes the adjustment of the multi-beam particle microscope 1 more difficult since a contribution of the beam splitter 400 to a possible maladjustment cannot be examined separately.

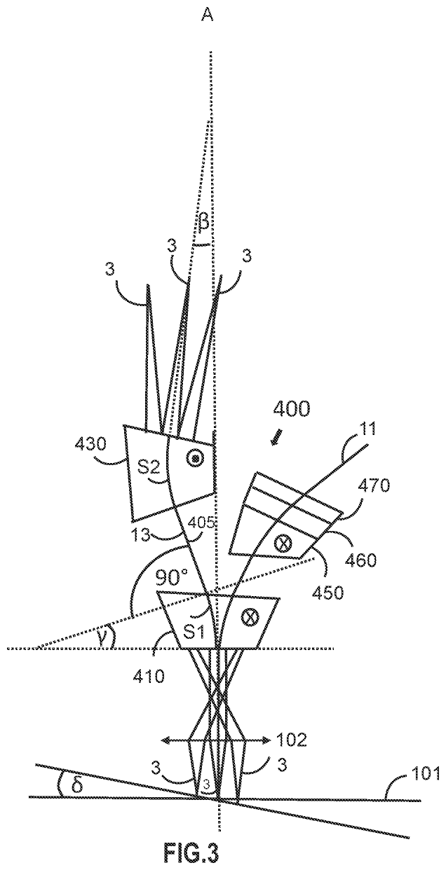

FIG. 3 schematically shows a magnet arrangement according to the prior art and the occurrence of a field inclination. In the example shown, the magnet arrangement 400 comprises a first magnetic field region 410 and a second magnetic field region 430, the magnetic fields of which are oriented in the opposite sense to one another, and a primary particle-optical beam path 13 travels through both of these magnetic field regions. Moreover, three further magnetic field regions 450, 460 and 470 are provided in the example shown. The secondary particle-optical beam path 11 extends through the first magnetic field region 410 and through these additional magnetic field regions 450, 460 and 470. The magnetic field in the magnetic field region 450 is oriented in the same direction as the magnetic field in the magnetic field region 410, with the result that the curvature of the second particle-optical beam path 11 is without a change of curvature in these magnetic field regions 410, 450.

The beam splitter shown in FIG. 3 is not of an aligned optical axes type: Instead, there is a skew angle β between the optical axis of the first particle-optical beam path 13 and the axis A, which corresponds to the optical axis of the objective lens 102 or the continuation thereof. A right angle is set between a lower edge of the first magnetic field region 410 and the axis A, which can be desirable for the properties of imaging into the object plane 101 overall. The skew angle β involves specific precision measurements when a multi-beam particle microscope 1 is manufactured, the measurements being considerably more time-consuming and cost-intensive than in the case of an aligned optical axes type or Cartesian arrangement, in which the skew angle β would be zero.

The angle y is the so-called splitting angle, which provides a measure for the separation of the primary particle-optical beam path 13 from the second particle-optical beam path 11 within the magnetic field region 410. This angle is not chosen to be too small, otherwise there might not be sufficient installation space available for the arrangement of magnetic field regions 450, 460 and 470 in the secondary particle-optical beam path 11.

Imaging aberrations of the first particle-optical beam path 13 may be largely corrected and the imaging can be substantially stigmatic to first order and substantially distortion-free to first order. However, there are ever greater demands on the resolution within the scope of ever more accurate measurement tasks for multi-beam particle microscopes 1 and it turned out that a field inclination d of the beam splitter 400 depicted in FIG. 3 often makes up the majority of the remaining residual aberration. In FIG. 3, this field inclination d′ has not been plotted true to scale. First individual particle beams 3 impinge the object or the object plane 101 at slightly different heights, wherein the location of the minimum particle beam diameter is considered to be the focus in this case. The individual particle beam 3 located exactly on the optical axis A has a focal position exactly on the object plane 101, the first individual particle beam 3 arranged to the left thereof has a focal position arranged just in front of the object plane 101 and the first individual particle beam 3 arranged to the right of the axis A has a focal position slightly below the object plane 101. The coming together of the field inclination d′is explained substantially by slightly different path lengths traversed by the plurality of the first individual particle beams 3 within the magnet arrangement 400. According to examinations by the inventors, the field inclination d cannot be compensated for as a result of the previous design with two magnetic field regions 410 and 430 and the provided skew angle β.

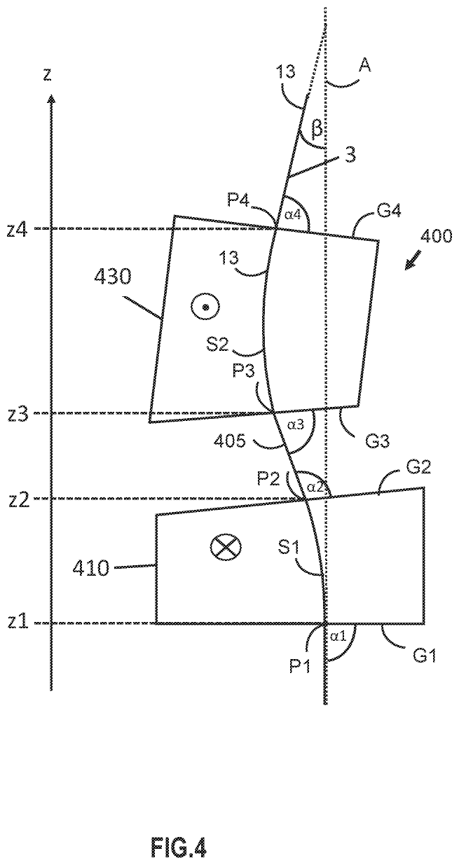

FIG. 4 schematically shows manipulation parameters in the case of a magnet arrangement 400 according to the prior art with two magnetic field regions 410 and 430 in the primary path 13; the secondary path has not been depicted in FIG. 4. In order to obtain a perpendicular emergence of the primary particle-optical beam path 13 from the first magnetic field region 410 and good imaging properties at the objective lens (not illustrated), the emergence point P1 and the inclination of the emergence region G4 are fixed in a design of the magnetic field arrangement 400, the angle al is 90° and the position in the direction of the Z-axis is defined as z1. Thus, the remaining entrance regions and exit regions into/from the magnetic field regions 410, 430 are available for the adaptation of particle-optical properties. By way of example, the points P2, P3 and P4 can be described by their z-positions z2, z3, z4 and by the angles α2, α3 and α4; however, other coordinates may naturally also be chosen to this end. In principle, the respective arc lengths S2 and S1 in the magnetic field regions 430 and 410 are adapted by an appropriate choice or definition of the points P2, P3 and P4. A drift path 405 is arranged between the points P2 and P3, the length of the drift path arising from the definition of the points P2 and P3.

If the point P1 is kept fixed, and the inclination G1 and the magnetic field strength in the magnetic field regions 410 and 430 are defined, then the system shown in FIG. 4 has a maximum of six independent manipulation parameters: the z-positions z2, z3 and z4 and the angles α2, α3 and α4. These six manipulation parameters can be used to optimize the imaging properties of the magnet arrangement 400 and reduce aberrations. However, a complete compensation of path differences and hence a substantial elimination of a field inclination in addition to already corrected aberrations is only possible, if at all, for certain incoming radiation conditions with the arrangement shown in FIG. 4.

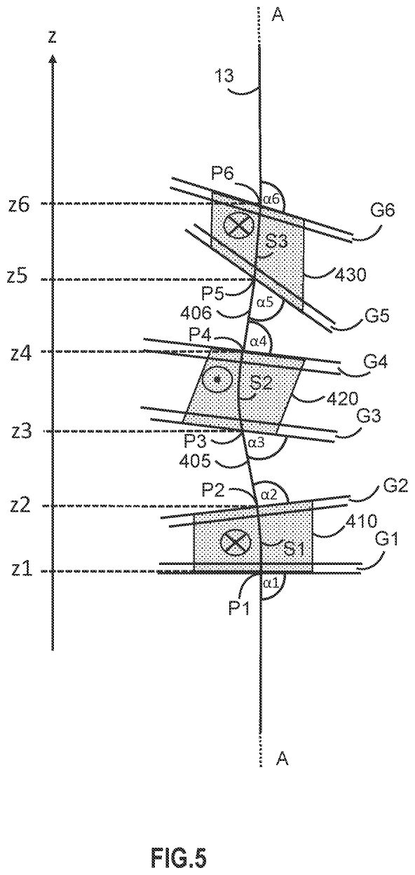

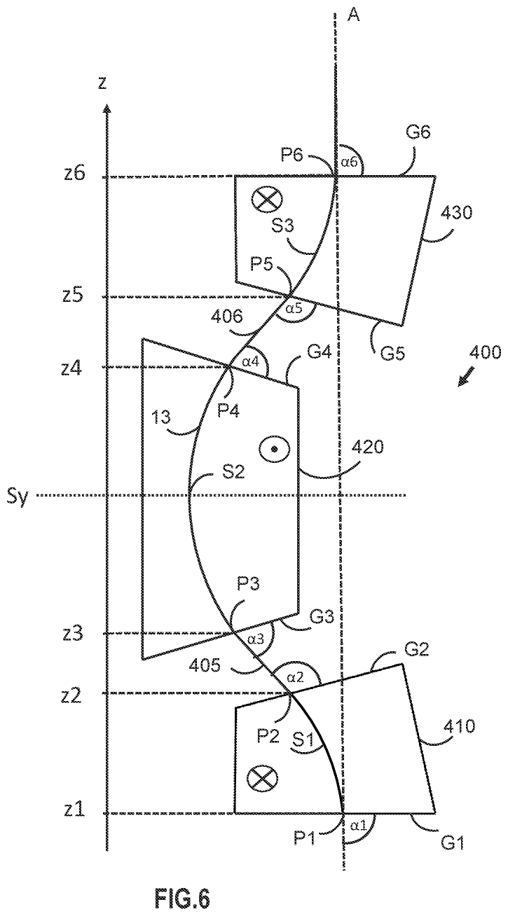

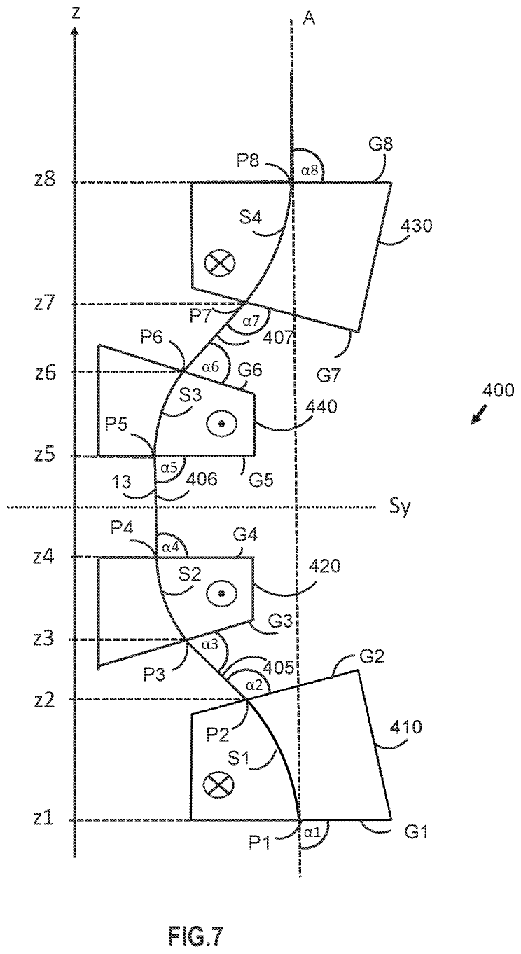

FIG. 5 schematically shows manipulation parameters in the case of a magnet arrangement 400 with three magnetic field regions 410, 420 and 430 in the primary path 13. The secondary path 11 has not been shown in FIG. 5 for reasons of clarity either; however, it may correspond to the arrangement shown in FIG. 3 with the magnetic field regions 450, 460 and 470. Other designs are also possible.

The magnet arrangement 400 in FIG. 5 is of the aligned optical axes type: an entrance direction of the primary particle-optical beam path 13 into the third magnetic field region 430 and an exit direction of the primary particle-optical beam path 13 from the first magnetic field region 410 are parallel to one another and without an offset. The directions correspond to the optical axis A, the direction of which corresponds to the optical axis of the objective lens 102 (not depicted here). The orientation of the first particle-optical beam path 13 upon emergence from the first magnetic field region 410 is defined and denoted by angle α1, which is 90°, in FIG. 5. In other words, an exit inclination of the first magnetic field region 410 is 0°; the exit region G1 (the letter G indicating a “trench”) is orthogonal to the z-axis, which is oriented parallel to the optical axis A. Moreover, the magnet arrangement 400 specifies that the magnetic field of the first magnetic field region 410 and the magnetic field of the third magnetic field region 430 deflect the primary particle-optical beam path 13 in substantially the same direction (in this case: into the plane of the drawing). In this case, the direction of the magnetic field is orthogonal to the z-axis and also to the optical axis A of the objective lens 102 (not depicted here). By contrast, the magnetic field in the second magnetic field region 420 is oriented in the opposite sense, with the result that the first magnetic field region 410 and the second magnetic field region 420 substantially deflect the primary particle-optical beam path 13 in different directions.

To change or define the particle-optical imaging properties of the magnet arrangement 400, the magnet arrangement 400, with a fixed point P1 (position and orientation), now comprises ten parameters that are adjustable independently of one another, specifically the z-positions z2, z3, z4, z5 and z6 and the angles α2, α3, α4, α5 and α6, which represent a measure for the inclinations of the trenches G2, G3, G4, G5 and G6. FIG. 5 plots the absolute inclination angles; however, it is naturally also possible to define the difference angle of the trenches G1 to G6 in relation to a horizontal arrangement of the trenches as a measure for the inclination. Moreover, the angles α1 to α6 were each chosen in relation to field-free regions (in this case the drift paths 405 and 406 or the regions outside of the magnet arrangement 400) because it is possible to directly plot the angle here. However, these definitions may also be made differently.

If it is not only the exit point P1 but also the entrance point P6, and hence the overall extent of the magnet arrangement 400 in the z-direction, which is defined in the arrangement according to FIG. 5, then the number of manipulation parameters reduces accordingly. If the inclination α6 is also defined, then there still are eight manipulation parameters.

To eliminate a beam splitter-induced field inclination, the magnet arrangement 400 according to FIG. 5 can be configured so that substantially no path differences arise for the plurality of first individual particle beams 3 when passing through the magnet arrangement 400.

FIG. 6 schematically shows a magnet arrangement 400 with a plane of symmetry Sy, in respect of which the primary particle-optical beam path 13 or the beam path of the chief ray is mirror symmetric when passing through the magnet arrangement 400. The magnet arrangement 400 comprises three magnetic field regions 410, 420 and 430 in the primary path 13 and is symmetrized. The secondary path 11 has not been depicted in FIG. 6 for reasons of clarity. However, the secondary path 11 may be designed as has already been described hereinabove in the context of other exemplary embodiments.

The plane of symmetry Sy intersects the second magnetic field region 420, to be precise centrally. In the case of the symmetrized magnet arrangement 400, the angles α1 and α6 are identical and are 90° in the example shown. The exit inclination of the first magnetic field region 410 is therefore 0° with respect to the horizontal; the same applies to the entrance inclination of the third magnetic field region 430. The angles α2 and α5 as well as α3 and α4 correspond to one another. The z-positions z1 and z6 have the same distance from the plane of symmetry Sy; the same applies to the pairs z2 and z5 as well as z3 and z4. As a result of defining the symmetry, the magnet arrangement 400 still comprises a total of six manipulation parameters which can be defined independently of one another. These are just as many as in the example according to the prior art depicted in FIG. 4. It is possible to reduce or entirely compensate aberrations as a result of the more pronounced symmetrization of the magnet arrangement 400. To this end, it may be desirable to place further demands on the symmetry of the primary particle-optical beam path 13, for example in relation to the divergence. It may be desirable for each of the first individual particle beams 3 to enter the magnet arrangement 400 with a divergence Dᵢ and to exit the magnet arrangement 400 again with the same divergence, albeit with a reversed sign, which is to say −Dᵢ.

In the example shown, the magnetic field strengths of the sectors 410 and 430 are set to have the same strength, which contributes to the symmetrization. The oppositely directed magnetic field strength of the second magnetic field region 420 can likewise be chosen to be the same in terms of absolute value.

The particle-optical arrangement may further have a deflector arrangement (not depicted in FIG. 6) arranged upstream of the third magnetic field region 430 in the direction of the primary particle-optical beam path 13 and configured to set the entrance direction of the primary particle-optical beam path 13 into the third magnetic field region 430, and hence set the demanded entrance inclination, with an accuracy of +/−0.1° or better, in particular of +/−0.05° or better or of +/−0.025° or better, and configured to set the entrance location of the primary particle-optical beam path 13 into the third magnetic field region 430 with an accuracy of +/−0.3 mm or better, in particular of +/−0.1 mm or better or even +/−0.05 mm or better. By way of example, the deflector arrangement comprises two adjustment deflectors which can be adjusted precisely and independently of one another such that it is possible to set, precisely and independently of one another, both the offset and the skew of the first individual particle beams 3 upon entrance into the magnet arrangement 400. This prevents a possible recurrence of beam splitter aberrations, actually already corrected via the design of the magnet arrangement 400, such as field inclination, field astigmatism, global astigmatism or other second-or third-order aberrations in the case of a skewed or offset beam input coupling.

FIG. 7 schematically shows a further symmetrized magnet arrangement 400 with exactly four magnetic field regions 410, 420, 440 and 430 in the primary path. More manipulation parameters are provided as a result of using a total of four magnetic field regions 410, 420, 440 and 430 in the primary particle-optical beam path 13. However, manipulation parameters are lost again as a result of the symmetrization. This magnet arrangement 400 is also of the aligned optical axes type. The angles α1 and α8 are defined, just like the positions z1 and z8 or the points P1 and P8. The angles α2 and α7, α3 and α6 as well as α4 and α5 are equal in terms of absolute value. A plane of symmetry Sy is arranged between the second magnetic field region 420 and the fourth magnetic field region 440. The points P4 and P5 have the same distance from the plane of symmetry Sy; the same applies to the points P3 and P6 as well as P2 and P7, and also to the points P1 and P8 or to the respective z-coordinates. In the case of such a definition, there then are three manipulation parameters from the angles α2, α3 and α4 and three manipulation parameters from the z-positions z2, z3 and z4 on account of the demanded symmetry conditions. By contrast, if the entrance locations P1 and P8 are not both defined at the same time, but for example only the exit location P1, then it is possible to obtain an additional manipulation parameter for a z-position. This displaces the position of the plane of symmetry Sy or, in principle, the distance between the z-positions z4 and z5 is varied. Naturally, it is possible here again to dissolve and release even more symmetries and, in theory, up to 16 manipulation parameters are obtainable as a result of the four parts of the magnet arrangement 400 in the primary path. The introduction of a symmetrization reduces the number of these manipulation parameters but can compensate aberrations. Moreover, five second-order aberration terms (of a total of 18 linearly independent second-order aberration terms) are eliminated as a result of the symmetric design of the magnet arrangement 400. In particular, a field inclination induced by the magnet arrangement 400 can be compensated for, or it does not even arise.

In the case of the symmetrized magnet arrangements 400 depicted in FIGS. 6 and 7, a sum of products of the signed absolute value of the magnetic field strength and an associated circular arc length in a magnetic field region 410, 420, 440, 430, along which the primary particle-optical beam path 13 travels in the magnetic field region 410, 420, 440 and 430, summed over all magnetic field regions 410, 420, 440, 430 in the primary particle-optical beam path 13 is zero. The magnetic fields are homogeneous and usually do not carry a sign; however, this sign is used mathematically in order to define the direction of the magnetic field. Expressed differently, the sign specifies the direction of the magnetic field in relation to a preferred axis perpendicular to the deflection plane, within the sense of a vector product. Specifically, in the embodiment depicted in FIG. 6, the following sum of products is zero for the central beam: M430*S3+M420*S2+M410*S1=0.

Moreover, the length of the drift paths 406 and 405 is identical. Overall, this consequently yields a condition for the aligned optical axes property of the magnet arrangement 400. The aforementioned conditions need not apply in this way to off-axis, divergent first individual particle beams 3.

For the exemplary embodiment depicted in FIG. 7, the following sum of products is zero in order to fulfil the aligned optical axes condition: M430S4+M440*3+M420*S2+M410*S1. Moreover, the drift paths 405 and 407 have an identical length; the drift path 406 extends parallel to the z-axis or to the optical axis A (extension of the optical axis of the objective lens). In principle, the length of the drift path 406 can be chosen freely; it can be used as a further manipulation parameter for a target variable to be set.

It can be desirable for the following relation to apply to a splitting angle y through which the primary particle-optical beam path 13 is deflected overall in the first magnetic field region 410 during the operation of the particle-optical arrangement: γ≥2°, such as γ≥5°,for example γ≥10°.

It was moreover found to be beneficial if an overall length of the magnet arrangement 400, as defined by a distance between the entrance point (P6, P8) of the primary particle-optical beam path 13 into the third magnetic field region 430 and the exit point P1 of the primary particle-optical beam path 13 from the first magnetic field region 410, is less than or equal to 1.0 m, such as than or equal to 0.5 m, for example less than or equal to 0.3 m.

Moreover, it can be desirable if the magnet arrangements 400 according to the disclosure do not comprise a beam tube arrangement in which the primary particle-optical beam path 13 runs within the magnet arrangement 400. Instead, the magnet arrangement 400 can have a vacuum chamber, in which the primary particle-optical beam path extends within the magnet arrangement 400. Thus, even if the magnet arrangement 400 is switched off, it is possible to ensure that the first individual particle beams 3 pass through the magnet arrangement 400 or emerge from the magnet arrangement 400 at the exit point P1, which is identical to the exit point P1 when the magnet arrangement 400 is switched on. This facilitates an adjustment of a multi-beam particle microscope 1 and can be a substantial benefit of an aligned optical axes design of the magnet arrangement 400.

According to an alternative exemplary embodiment, the magnet arrangement 400 nevertheless has a beam tube arrangement (not depicted here), within which the primary particle-optical beam path 13 extends within the magnet arrangement 400, wherein the beam tube arrangement has the topological form of a torus. As a result, the aligned optical axes property of the magnet arrangement 400 can be used for adjustment purposes when the primary path beam splitter is switched off or when magnetic field regions 410, 420, 430, 440 in the primary particle-optical beam path 13 are switched off. The torus topology describes very generally two branches of the beam tube arrangement, wherein, when the magnetic field regions 410, 420, 430, 440 are switched off, the primary particle-optical beam path 13 can branch off at the first branching and can be coupled back in at the second branching.

According to an embodiment of the disclosure, the following relation applies to a fill factor F of the beam tube arrangement during the operation of the particle-optical arrangement: F≤50%, such as F≤30%, for example F≤10%. In this case, the fill factor is given as the ratio of the maximum diameter S of a beam (the totality of the primary individual particle beams) to the internal diameter R of the beam tube or the beam tube arrangement. In this case, the beam tube is made of a non-magnetic material. For a given maximum diameter S of the beam, the internal diameter R of the beam tube can be dimensioned accordingly. This minimizes the contamination of the beam tube as a result of the interaction with the charged particle beams 3, 9 during operation, in order to avoid unwanted beam deflections on account of charged contamination spots on the inner side of the beam tube.

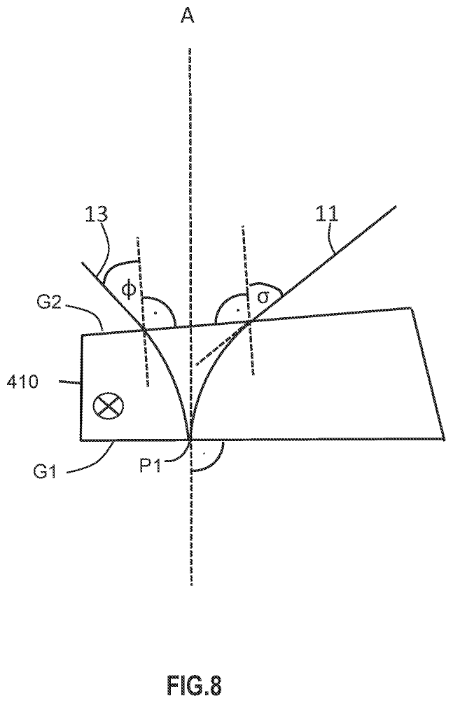

FIG. 8 schematically illustrates an arrangement or alignment of the first magnetic field region 410 in the particle-optical beam path. The exit inclination of the exit region or trench G1 from the first magnetic field region 410 is also 0°, like in the previous exemplary embodiments. Consequently, there is a right angle between the exit region or trench G1 and the axis A. The exit direction from the first magnetic field region 410 corresponds in particular to the direction of the particle-optical axis of the objective lens 102 if the particle-optical arrangement is arranged in a multi-beam particle microscope 1. The secondary particle beams 9, for example electron beams, which travel through the secondary particle-optical beam path 11 during the operation of the particle-optical arrangement usually have a lower kinetic energy than the primary particle beams 3. The secondary particles 9 are therefore slower and are deflected more strongly in the first magnetic field region 410 or a trajectory radius r_{B} of the trajectory described thereby in the homogeneous magnetic field is smaller than a corresponding trajectory radius of the faster primary particles 3 or electrons. The exit angle o of the secondary particle-optical beam path 11 therefore, as a matter of principle, differs from the entrance angle Φ of the primary beams 3 of the primary particle-optical beam path 13, even in the case of an orthogonal alignment of the trench G2 with respect to the axis A. The entrance angle Φ and the exit angle o can be defined by the entrance inclination of the first magnetic field region 410 or trench G2. In the process, it can be desirable to limit the exit angle σ of the secondary particle-optical beam path 11 from this first magnetic field region 410 to σ≤35°, such as σ≤25° or σ≤15°. This avoids the collection of large aberrations when emerging from the first magnetic field region 410 and creates additional installation space for possible additional secondary path magnetic field regions in the gap between the first magnetic field region 410 and the second magnetic field region 420. According to a further exemplary embodiment, at least one of the further magnetic field regions of the secondary particle-optical beam path 11 is arranged in a gap between the first magnetic field region 410 and the second magnetic field region 420 of the primary particle-optical beam path 13.

By way of example, the magnet arrangement 400 can have at least two further magnetic field regions in the secondary particle-optical beam path 11 following the passage of the first magnetic field region 410, the at least two further magnetic field regions being configured, in the case of a varying energy of secondary particles whose path forms the second particle-optical beam path 11, to precisely input couple, in terms of offset and angle, the particle-optical axis Z in the secondary beam path 11 into a downstream projection optical unit 200 (see for example FIG. 1). By way of example, the varying energy of the secondary particles 9 may be the result of a modified setting of a landing energy.

According to an exemplary embodiment, the magnet arrangement 400 has at least six further magnetic field regions and/or quadrupole fields in the secondary particle-optical beam path 11 following the passage of the first magnetic field region 410, the at least six further magnetic field regions and/or quadrupole fields being configured, in the case of a varying energy of secondary particles 9 whose path forms the second particle-optical beam path 11, to precisely input couple, in terms of offset and angle, the particle-optical axis Z in the secondary beam path 1 into a downstream projection optical unit 200 (see for example FIG. 1) and additionally enable paraxial stigmatic, paraxial distortion-free and paraxial dispersion-free imaging.

According to a further exemplary embodiment, the magnet arrangement 400 further has a magnetic shielding wall arranged between at least one of the magnetic field regions 410, 420, 430, 440 of the primary particle-optical beam path 13 and at least one of the magnetic field regions of the secondary particle-optical beam path 11. Naturally, it may also be arranged substantially continuously between all magnetic field regions 410, 420, 430, 440 of the primary particle-optical beam path 13 and all magnetic field regions of the secondary particle-optical beam path 11. By way of example, the magnetic shielding wall comprises a web of soft magnetic material, which minimizes crosstalk between primary path and secondary path magnetic field regions.

According to a further exemplary embodiment, the magnetic shielding wall has an opening channel, through which the first particle-optical beam path passes in a straight line along the particle-optical axis when the magnet arrangement is switched off. As a result, the aligned optical axes property of the magnet arrangement when the magnetic field regions of the primary path are switched off can be used for adjustment purposes. The opening channel can be characterized by the ratio K of channel length L to channel width B. For example, in the case of K≥3, such as K≥5 or K≥10, the magnetic shield between the magnetic field regions of the primary path and secondary path is well ensured despite the opening channel.

The magnet arrangements 400 according to the disclosure can also be integrated in a multi-beam particle microscope 1, for example into the one depicted schematically in FIG. 1, just like the magnet arrangements 400 according to the prior art.

According to an exemplary embodiment, imaging of the plurality of the first individual particle beams 3 onto the object plane 101 exhibits substantially no field inclination. Naturally, it is also possible to correct other imaging aberrations by way of an appropriate design of the magnet arrangement 400, as has also already been described in detail hereinabove. According to an exemplary embodiment, the imaging of the plurality of the first individual particle beams 3 into the object plane 101 is substantially distortion-free overall, and/or the imaging of the first individual particle beams 3 into the object plane 101 is substantially dispersion-free, and/or the incidence locations 5 of the first individual particle beams 3 in the object plane 101 are astigmatic and round. In addition, or as an alternative, it is also possible to correct other aberrations within the scope of the particle-optical imaging. Depending on the design, the magnet arrangement 400 according to the disclosure offers appropriate manipulation parameters for correction purposes. The correction may also comprise a correction of a skew of the sample and/or a correction of a focal tilt as a result of a maladjustment of an illumination system/condenser lens system.

According to an exemplary embodiment, the imaging of the first individual particle beams 3 into the object plane 101 is field astigmatism-free. Additionally, what may apply is that the sum of all other aberrations of second and third order in the object plane 101 is no more than only 1 nm, such as no more than only 0.5 nm or no more than only 0.25 nm.

Further exemplary embodiments are listed hereinbelow:

Example 1. Particle-optical arrangement for providing a primary particle-optical beam path for a plurality of first individual particle beams which, emanating from a multi-beam particle generator, are directed at an object positionable in an object plane of the arrangement, and a secondary particle-optical-beam path for a plurality of second individual particle beams which emanate from the object,
wherein the particle-optical arrangement has a magnet arrangement comprising:
a first magnetic field region through which the primary particle-optical beam path and the second particle-optical beam path pass, for the separation of the primary particle-optical beam path and the secondary particle-optical beam path from one another;
   a second magnetic field region arranged in the primary particle-optical beam path and not arranged in the secondary particle-optical beam path, the second magnetic field region being arranged upstream of the first magnetic field region in relation to the primary particle-optical beam path and the first magnetic field region and the second magnetic field region substantially deflecting the primary particle-optical beam path in different directions;
   a third magnetic field region arranged in the primary particle-optical beam path and not arranged in the secondary particle-optical beam path, the third magnetic field region being arranged upstream of the second magnetic field region in relation to the primary particle-optical beam path and the first and the third magnetic field region substantially deflecting the primary particle-optical beam path in the same direction,
   an entrance direction of the primary particle-optical beam path into the third magnetic field region and an exit direction of the primary particle-optical beam path from the first magnetic field region being substantially parallel to one another and substantially without an offset.

Example 2. Particle-optical arrangement according to the preceding example,
wherein a first drift region, which is substantially free from magnetic fields, is arranged in the primary particle-optical beam path between the first magnetic field region and the second magnetic field region; and/or
wherein a second drift region, which is substantially free from magnetic fields, is arranged in the primary particle-optical beam path between the second magnetic field region and the third magnetic field region.

Example 3. Particle-optical arrangement according to example 1,
wherein the magnet arrangement has a fourth magnetic field region which is arranged in the primary particle-optical beam path and not arranged in the secondary particle-optical beam path, wherein the fourth magnetic field region is arranged upstream of the second magnetic field region and downstream of the third magnetic field region in relation to the primary particle-optical beam path, and
wherein the fourth magnetic field region and the second magnetic field region substantially deflect the primary particle-optical beam path in the same direction.

Example 4. Particle-optical arrangement according to the preceding example,
wherein a first drift region, which is substantially free from magnetic fields, is arranged in the primary particle-optical beam path between the first magnetic field region and the second magnetic field region; and/or
wherein a second drift region, which is substantially free from magnetic fields, is arranged in the primary particle-optical beam path between the second magnetic field region and the fourth magnetic field region; and/or
wherein a third drift region, which is substantially free from magnetic fields, is arranged in the primary particle-optical beam path between the fourth magnetic field region and the third magnetic field region.

Example 5. Particle-optical arrangement according to any of the preceding examples,
wherein the magnet arrangement has no further magnetic field regions in the primary particle-optical beam path which are designed to deflect the primary particle-optical beam path by more than 2°, in particular 1° or 0.5°.

Example 6. Particle-optical arrangement according to any of the preceding examples,
wherein the magnet arrangement is configured so that substantially no path differences arise for the plurality of the first individual particle beams as these pass through the magnet arrangement.

Example 7. Particle-optical arrangement according to any of the preceding examples,
wherein the magnet arrangement has a plane of symmetry, in relation to which the primary particle-optical beam path is mirror symmetric when passing through the magnet arrangement.

Example 8. Particle-optical arrangement according to examples 3 and 7,
wherein the plane of symmetry intersects the second magnetic field region.

Example 9. Particle-optical arrangement according to examples 5 and 7,
wherein the plane of symmetry is arranged between the second magnetic field region and the fourth magnetic field region.

Example 10. Particle-optical arrangement according to any of the preceding examples,
wherein the direction of the magnetic fields in all of the magnetic field regions of the magnet arrangement is substantially orthogonal to the optical axis of the primary particle-optical beam path during the operation of the particle-optical arrangement and wherein the magnetic fields are substantially homogeneous.

Example 11. Particle-optical arrangement according to the preceding example,
wherein the homogeneous magnetic fields in the magnetic field regions in the primary particle-optical beam path each have an absolute value of the magnetic field strength during the operation of the particle-optical arrangement and wherein the magnetic fields are each assigned a sign, the sign characterizing the direction of the magnetic field, and
wherein the sum of the products of the signed absolute value of the magnetic field strength and an associated circular arc length in a magnetic field region, along which the primary particle-optical beam path travels in the magnetic field region, summed over all magnetic field regions in the primary particle-optical beam path yields substantially zero.

Example 12. Particle-optical arrangement according to any of the preceding examples,
wherein the following relation applies to a splitting angle y through which the primary particle-optical beam path is deflected overall in the first magnetic field region during the operation of the particle-optical arrangement: γ≥2°, in particular γ≥5° or γ≥10°.

Example 13. Particle-optical arrangement according to any of the preceding examples,
wherein an overall length of the magnet arrangement, as defined by a distance between the entrance point of the primary particle-optical beam path into the third magnetic field region and the exit point of the primary particle-optical beam path from the first magnetic field region, is less than or equal to 1.0 m, in particular less than or equal to 0.5 m or less and or equal to 0.3 m.

Example 14. Particle-optical arrangement according to any of the preceding examples,
wherein each magnetic field region has an entrance region for the primary particle-optical beam path with an entrance inclination and an exit region for the primary particle-optical beam path with an exit inclination,
wherein the entrance inclination is defined as the angle by which the alignment of the entrance region deviates from the normal to the optical axis of the primary particle-optical beam path, and
wherein the exit inclination is defined as the angle by which the alignment of the exit region deviates from the normal to the optical axis of the primary particle-optical beam path, and
wherein the exit inclination of the first magnetic field region is 0°.

Example 15. Particle-optical arrangement according to the preceding example,
wherein the entrance inclination of the third magnetic field region is 0°.

Example 16. Particle-optical arrangement according to any of the preceding examples,
wherein the magnet arrangement comprises no beam tube arrangement, in which the primary particle-optical beam path extends within the magnet arrangement.

Example 17. Particle-optical arrangement according to the preceding example,
wherein the magnet arrangement has a vacuum chamber, in which the primary particle-optical beam path extends within the magnet arrangement.

Example 18. Particle-optical arrangement according to any of the preceding examples,
wherein no intermediate image of the plurality of first individual particle beams is arranged in the primary particle-optical beam path within the magnet arrangement; and/or
wherein no cross-over of the plurality of first individual particle beams with one another is formed in the primary particle-optical beam path within the magnet arrangement.

Example 19. Particle-optical arrangement according to any of the preceding examples,
wherein the magnet arrangement has at least one further magnetic field region in the secondary particle-optical beam path.

Example 20. Particle-optical arrangement according to any of the preceding examples,
wherein the particle-optical arrangement is a multi-beam particle microscope and wherein the particle-optical arrangement further has the following:
a multi-beam particle generator, which is configured to generate a first field of a plurality of charged first individual particle beams;
a first particle-optical unit with a primary particle-optical beam path, configured to image the generated first individual particle beams onto an object plane such that the first individual particle beams impinge an object at incidence locations, which form a second field;
a detection unit with a plurality of detection regions which form a third field;
a second particle-optical unit with a secondary particle-optical beam path, configured to image second individual particle beams, which emanate from the incidence locations in the second field, onto the third field of the detection regions of the detection system;
a magnetic and/or electrostatic objective lens, through which both the first and the second individual particle beams pass; and
a controller, configured to control particle-optical components in the primary and/or in the secondary particle-optical beam path and/or components of the magnet arrangement,
wherein the magnet arrangement is arranged in the primary particle-optical beam path between the multi-beam particle generator and the objective lens and wherein the magnet arrangement is arranged in the secondary particle-optical beam path between the objective lens and the detection unit.

Example 21. Particle-optical arrangement according to the preceding example,
wherein the imaging of the plurality of the first individual particle beams onto the object plane exhibits substantially no field inclination.

Example 22. Particle-optical arrangement according to any of examples 20 to 21,
wherein the imaging of the plurality of the first individual particle beams into the object plane is substantially distortion-free overall, and/or
wherein the imaging of the first individual particle beams into the object plane is substantially dispersion-free, and/or
wherein the incidence locations of the individual particle beams in the object plane are astigmatic and round.

### LIST OF REFERENCE SIGNS

1 Multi-beam particle microscope
3 Primary particle beams (individual particle beams)
5 Beam spots, incidence locations
7 Object, sample
9 Secondary particle beams
10 Computer system, controller
11 Secondary particle-optical beam path
13 Primary particle-optical beam path
15 Sample surface
101 Object plane
102 Objective lens
105 Axis
200 Detector system
205 Projection lens system
209 Detection system, particle multi-detector, detection unit
210 Lens
220 Lens
222 Contrast stop
260 Anti-scan
300 Beam generating apparatus
301 Particle source
303 Collimation lens system
305 Multi-aperture arrangement
306 Micro-optics
307 Field lens
308 Field lens
309 Diverging particle beam
323 Beam foci
325 Intermediate image plane
400 Beam splitter, magnet arrangement
405 Drift path
406 Drift path
407 Drift path
410 Magnetic field region
420 Magnetic field region
430 Magnetic field region
440 Magnetic field region
450 Magnetic field region
460 Magnetic field region
461 Limb of the beam tube arrangement
462 Limb of the beam tube arrangement
463 Limb of the beam tube arrangement
466 Branching point
470 Magnetic field region
490 Beam tube arrangement
500 Scan deflector
600 Displacement stage or positioning device
A Axis
z1 . . . z8 z-positions
α1 . . . α8 Inclination angles
β Skew angle
γ Splitting angle
δ Field inclination angle
σ Exit angle
Φ Entrance angle
G1 . . . G8 Magnetic field region edge, trench, depression
P1 . . . P8 Point, position
S1 . . . S4 Length of a circular arc
Sy Plane of symmetry

What is claimed is:

1. A particle-optical arrangement configured to provide a primary particle-optical beam path for a plurality of first individual particle beams which emanate from a multi-beam particle generator and are directed at an object plane of the particle-optical arrangement, the particle-optical arrangement also configured to provide a secondary particle-optical beam path for a plurality of second individual particle beams which emanate from the object plane of the particle-optical arrangement, the particle-optical arrangement, comprising:
a magnet arrangement, comprising:
a first magnetic field region disposed in the primary and secondary particle-optical beam paths;
a second magnetic field region disposed in the primary particle-optical beam path upstream of the first magnetic field region, the second magnetic field region not disposed in the secondary particle-optical beam path; and
a third magnetic field region disposed in the primary particle-optical beam path upstream of the second magnetic field region, the third magnetic region not disposed in the secondary particle-optical beam path,
wherein:
the first magnetic region is configured to separate the primary particle-optical beam path from the secondary particle-optical beam path;
the first and second magnetic field regions are configured to substantially deflect the primary particle-optical beam path in different directions; and
the first and the third magnetic field regions are configured to substantially deflect the primary particle-optical beam path in the same direction;
the primary particle beam has an entrance direction into the third magnetic field region;
the primary particle beam has an exit direction out of the first magnetic field region;
the entrance direction is parallel to the exit direction; and
the entrance direction is not offset relative to the exit direction.

2. The particle-optical arrangement of claim 1, wherein:
a drift region, which is substantially free from magnetic fields, is disposed in the primary particle-optical beam path between the first and second magnetic field regions; and/or
a drift region, which is substantially free from magnetic fields, is disposed in the primary particle-optical beam path between the second and third magnetic field regions.

3. The particle-optical arrangement of claim 1, wherein:
the magnet arrangement further comprises a fourth magnetic field region;
the fourth magnetic field region is disposed in the primary particle-optical beam path between the second and third magnetic field regions;
the fourth magnetic field region is not disposed in the secondary particle-optical beam path; and
the fourth magnetic field region and the second magnetic field region substantially deflect the primary particle-optical beam path in the same direction.

4. The particle-optical arrangement of claim 3, wherein:
a drift region, which is substantially free from magnetic fields, is disposed in the primary particle-optical beam path between the first and second magnetic field region; and/or
a drift region, which is substantially free from magnetic fields, is disposed in the primary particle-optical beam path between the second and fourth magnetic field regions; and/or
a drift region, which is substantially free from magnetic fields, is disposed in the primary particle-optical beam path between the third and fourth magnetic field regions.

5. The particle-optical arrangement of claim 1, wherein the magnet arrangement has no further magnetic field regions in the primary particle-optical beam path which are configured to deflect the primary particle-optical beam path by more than 2°.

6. The particle-optical arrangement of claim 1, wherein the magnet arrangement is configured so that substantially no path differences arise for the plurality of the first individual particle beams as they pass through the magnet arrangement.

7. The particle-optical arrangement of claim 1, wherein, when passing through the magnet arrangement, the primary particle-optical beam path is mirror symmetric to a plane of symmetry of the magnet arrangement.

8. The particle-optical arrangement of claim 7, wherein the plane of symmetry intersects the second magnetic field region.

9. The particle-optical arrangement of claim 7, wherein the plane of symmetry is between the second and fourth magnetic field regions.

10. The particle-optical arrangement of claim 1, wherein the particle-optical arrangement is configured so that during use of the particle-optical arrangement:
a direction of the magnetic fields in all of the magnetic field regions of the magnet arrangement is substantially orthogonal to an optical axis of the primary particle-optical beam path; and
the magnetic fields in all of the magnetic field regions of the magnet arrangement are substantially homogeneous.

11. The particle-optical arrangement of claim 10, wherein the particle-optical arrangement is configured so that during use of the particle-optical arrangement:
each of the homogeneous magnetic fields has an absolute value of its magnetic field strength
each of the magnetic fields has a sign characterizing a direction of the magnetic field; and
a sum of the products of the assigned absolute value of the magnetic field strength and an associated circular arc length in a magnetic field region, along which the primary particle-optical beam path travels in the magnetic field region, summed over all magnetic field regions in the primary particle-optical beam path is substantially zero.

12. The particle-optical arrangement of claim 1, wherein, for a splitting angle through which the primary particle-optical beam path is deflected overall in the first magnetic field region during use of the particle-optical arrangement is at least 2°.

13. The particle-optical arrangement of claim 1, wherein a distance between an entrance and of the primary particle-optical beam path into the third magnetic field region and an exit point of the primary particle-optical beam path from the first magnetic field region is at most one meter.

14. The particle-optical arrangement of claim 1, wherein for each magnetic field region:
the magnetic field region has an entrance region for the primary particle-optical beam path with an entrance inclination and an exit region for the primary particle-optical beam path with an exit inclination;
the entrance inclination is an angle by which an alignment of the entrance region deviates from a normal to the optical axis of the primary particle-optical beam path;
the exit inclination is an angle by which an alignment of the exit region deviates from the normal to the optical axis of the primary particle-optical beam path; and
the exit inclination of the first magnetic field region is 0°.

15. The particle-optical arrangement of claim 14, wherein the entrance inclination of the third magnetic field region is 0°.

16. The particle-optical arrangement of claim 1, further comprising a deflector arrangement, wherein:
the deflector arrangement is disposed upstream of the third magnetic field region in the direction of the primary particle-optical beam path;
the deflector arrangement is configured to set the entrance;
the deflector arrange is configured to set an entrance inclination of the primary particle-optical beam path into the third magnetic field region with an accuracy of least 0.1°; and
the deflector arrangement is configured to set an entrance location of the primary particle-optical beam path into the third magnetic field region with an accuracy of at least 0.3 millimeter.

17. The particle-optical arrangement of claim 14, wherein particle-optical arrangement is configured so that the entrance inclination of the first magnetic field region is selectable so that an exit angle of the secondary particle-optical beam path from the first magnetic field region is restricted to at most 35°.

18. The particle-optical arrangement of claim 1, wherein the magnet arrangement further comprises a beam tube arrangement within which the primary particle-optical beam path extends within the magnet arrangement, and wherein the beam tube arrangement is shaped as a torus.

19. The particle-optical arrangement of claim 18, wherein a fill factor of the beam tube arrangement is at most 50%.

20. The particle-optical arrangement of claim 1, wherein the magnet arrangement does not comprise a beam tube arrangement in which the primary particle-optical beam path extends within the magnet arrangement.

21. The particle-optical arrangement of claim 20, wherein the magnet arrangement comprises a vacuum chamber in which the primary particle-optical beam path extends within the magnet arrangement.

22. The particle-optical arrangement of claim 21, wherein the magnet arrangement comprises a further magnetic field region in the secondary particle-optical beam path.

23. The particle-optical arrangement of claim 21, wherein:
the magnet arrangement comprises two further magnetic field regions in the secondary beam path following the passage of the first magnetic field region; and
the two further magnetic field regions are configured, so that, in a case of a varying energy of secondary particles whose path forms the second particle-optical beam path, the two further magnetic field regions precisely input couple, in terms of offset and angle, the particle-optical axis in the secondary beam path into a downstream projection optical unit.

24. The particle-optical arrangement of claim 21, wherein:
the magnet arrangement comprises six further magnetic field regions and/or quadrupole fields in the secondary beam path following the passage of the first magnetic field region;
the six further magnetic field regions and/or quadrupole fields are configured so that, in a case of a varying energy of secondary particles whose path forms the second particle-optical beam path, the six further magnetic field regions and/or quadrupole fields precisely input couple, in terms of offset and angle, the particle-optical axis in the secondary beam path into a downstream projection optical unit and additionally enable paraxial stigmatic, paraxial distortion-free and paraxial dispersion-free imaging.

25. The particle-optical arrangement of claim 22, wherein the further magnetic field regions of the secondary particle-optical beam path are in a gap along the primary particle-optical beam path between the first and second magnetic field regions.

26. The particle-optical arrangement of claim 22, further comprising a magnetic shielding wall between a magnetic field region of the primary particle-optical beam path and a magnetic field region of the secondary particle-optical beam path.

27. The particle-optical arrangement of claim 26, wherein the magnetic shielding wall has an opening channel through which the first particle-optical beam path passes in a straight line along an particle-optical axis of the particle-optical arrangement when the magnet arrangement is switched off.

28. The particle-optical arrangement of claim 1, wherein:
the particle-optical arrangement is a multi-beam particle microscope;
the particle-optical arrangement further comprises:
a multi-beam particle generator configured to generate a first field of a plurality of charged first individual particle beams;
a first particle-optical unit with a primary particle-optical beam path, the first particle-optical unit configured to image the first individual particle beams onto the object plane so that the first individual particle beams impinge on an object in the object plane at incidence locations which form a second field;
a detection unit comprising a plurality of detection regions which form a third field;
a second particle-optical unit with a secondary particle-optical beam path, the second particle-optical unit configured to image second individual particle beams which emanate from the incidence locations in the second field onto the third field of the detection regions of the detection system;
a magnetic and/or electrostatic objective lens through which both the first and the second individual particle beams pass; and
a controller configured to control particle-optical components in the primary and/or in the secondary particle-optical beam path and/or components of the magnet arrangement,
the magnet arrangement is disposed in the primary particle-optical beam path between the multi-beam particle generator and the objective lens; and
the magnet arrangement is disposed in the secondary particle-optical beam path between the objective lens and the detection unit.

29. The particle-optical arrangement of claim 28, wherein imaging the plurality of the first individual particle beams onto the object plane exhibits substantially no field inclination.

30. The particle-optical arrangement of claim 28, wherein the particle-optical arrangement is configured so that during use of the particle-optical arrangement:
imaging the plurality of the first individual particle beams into the object plane is substantially distortion-free overall; and/or
imaging the first individual particle beams into the object plane is substantially dispersion-free; and/or
the incidence locations of the first individual particle beams in the object plane are astigmatic and round.

31. The particle-optical arrangement of claim 28, wherein the particle-optical arrangement is configured so that, during use of the particle-optical arrangement, imaging the first individual particle beams into the object plane is field astigmatism-free.

32. The particle-optical arrangement of claim 31, wherein the particle-optical arrangement is configured so that, during use of the particle-optical arrangement, a sum of all other aberrations of second and third order in the object plane is no more than one nanometer.
